(19) United States
(12) Patent Application Publication
(10) Pub. No.: US 2017/0200729 A1
(43) Pub. Date: Jul. 13, 2017

(54) INTEGRATED CIRCUIT AND PROCESS THEREOF

(71) Applicant: UNITED MICROELECTRONICS CORP., Hsin-Chu City (TW)

(72) Inventors: Tseng-Fang Dai, Tainan City (TW); Ping-Chia Shih, Tainan City (TW); Chi-Cheng Huang, Kaohsiung City (TW); Kun-I Chou, Tainan City (TW); Hung-Wei Lin, Kaohsiung City (TW); Ching-Wen Yang, Tainan City (TW)

(21) Appl. No.: 14/993,101

(22) Filed: Jan. 12, 2016

(51) Int. Cl. H01L 27/115; H01L 29/51; H01L 29/66

(52) U.S. Cl. CPC H01L 27/11534; H01L 27/11521; H01L 27/11568; H01L 27/11573; H01L 29/66545; H01L 29/513; H01L 29/518

(57) ABSTRACT

An integrated circuit process includes the following steps. A substrate including a flash cell area and a logic area is provided. A first sacrificial gate on the substrate of the flash cell area and a second sacrificial gate on the substrate of the logic area are formed, and a dielectric layer covers the substrate beside the first sacrificial gate and the second sacrificial gate. The first sacrificial gate is removed to forma first recess in the dielectric layer. An oxide/nitride/oxide layer is formed to conformally cover surfaces of the first recess. An integrated circuit formed by said integrated circuit process is also provided.

### BACKGROUND OF THE INVENTION

1. Field of the Invention

The present invention relates generally to an integrated circuit, and more specifically to an integrated circuit including logic gates and flash gates with metal gates therein, and a process thereof.

2. Description of the Prior Art

Microprocessor systems are able to handle data and arrange information and have therefore become an important asset in information development of our modern society. One of the most important structures in a microprocessor system is the memory used to store digital data and provide stored data for microprocessor systems. A flash memory or an EEPROM (electrically erasable programmable read only memory), thanks to electron operation, is able to store data in a non-volatile way, and can also read the stored data quickly and efficiently, unlike optical or magnetic storage media (such as discs or optical discs). Therefore, flash memories have been utilized widely in various microprocessor systems such as application chip systems, mobile phones, personal digital assistants, personal computers and digital cameras, due to their light volume and convenient and efficient operation.

A flash memory consists of MOS transistors with a floating gate, each serving as a memory cell for recording a bit data. The floating gate is located in an oxide layer, isolated from the body, the drain, the source, and the control gate. When storing data, proper bias voltages are required to be applied to the gate, the source, the drain, and the body so that the electrons can pass through the oxide layer and thus flow into the floating gate. A different amount of charges injected into the floating gate of the transistor corresponds to different data. For instance, if more charges are injected into the floating gate, the transistor stores a data bit “1”; if fewer charges are injected into the floating gate, the transistor stores a data bit “0”. The amount of charges injected into the floating gate will influence the threshold voltage of the transistor. The more negative charges injected into the floating gate of the transistor, the smaller the absolute value of the threshold voltage of the transistor. Under the circumstance of keeping the control voltage applied to the control gate, when there is more negative charge within the floating gate, the conduct performance associated with the transistor will be higher, so that the current between the source and drain of the transistor is increased. In other words, under the circumstance of keeping the control voltage applied on the control gate, the data bit stored in the transistor depends on the amount of conduct current in the transistor between its source and drain. When overwriting or erasing the original data stored in the memory transistor, the control gate, the body, the drain, and the source are still required to have proper bias voltages applied, which causes the electrons within the floating gate to pass through the oxide layer and flow into other electrodes of the transistor.

### SUMMARY OF THE INVENTION

The present invention provides an integrated circuit and a process thereof which integrates flash cells into metal gate processes to simply the associated process steps.

The present invention provides an integrated circuit process including the following steps. A substrate including a flash cell area and a logic area is provided. A first sacrificial gate on the substrate of the flash cell area and a second sacrificial gate on the substrate of the logic area are formed, and a dielectric layer covers the substrate beside the first sacrificial gate and the second sacrificial gate. The first sacrificial gate is removed to form a first recess in the dielectric layer. An oxide/nitride/oxide layer is formed to conformally cover surfaces of the first recess.

The present invention provides an integrated circuit including a substrate, a first gate and a second gate. The substrate includes a flash cell area and a logic area. The first gate is disposed on the substrate of the flash cell area and the second gate is disposed on the substrate of the logic area. An oxide/nitride/oxide layer is disposed below the first gate and a dielectric layer having a high dielectric constant is disposed below the second gate.

According to the above, the present invention provides an integrated circuit and process thereof, which forms a first sacrificial gate on a substrate of a flash cell area and a second sacrificial gate on the substrate of a logic area; covers a dielectric layer on the substrate beside the first sacrificial gate and the second sacrificial gate; removes the first sacrificial gate to forma first recess in the dielectric layer; and forms an oxide/nitride/oxide layer to conformally cover surfaces of the first recess. In this way, a flash cell including the oxide/nitride/oxide layer integrated with a logic cell can be fabricated in a simple way.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of an integrated circuit process according to an embodiment of the present invention.

FIG. 2 schematically depicts a cross-sectional view of an integrated circuit process according to the embodiment of the present invention.

FIG. 3 schematically depicts a cross-sectional view of an integrated circuit process according to the embodiment of the present invention.

FIG. 4 schematically depicts a cross-sectional view of an integrated circuit process according to the embodiment of the present invention.

FIG. 5 schematically depicts a cross-sectional view of an integrated circuit process according to the embodiment of the present invention.

FIG. 6 schematically depicts a cross-sectional view of an integrated circuit process according to the embodiment of the present invention.

FIG. 7 schematically depicts a cross-sectional view of an integrated circuit process according to the embodiment of the present invention.

FIG. 8 schematically depicts a cross-sectional view of an integrated circuit process according to the embodiment of the present invention.

### DETAILED DESCRIPTION

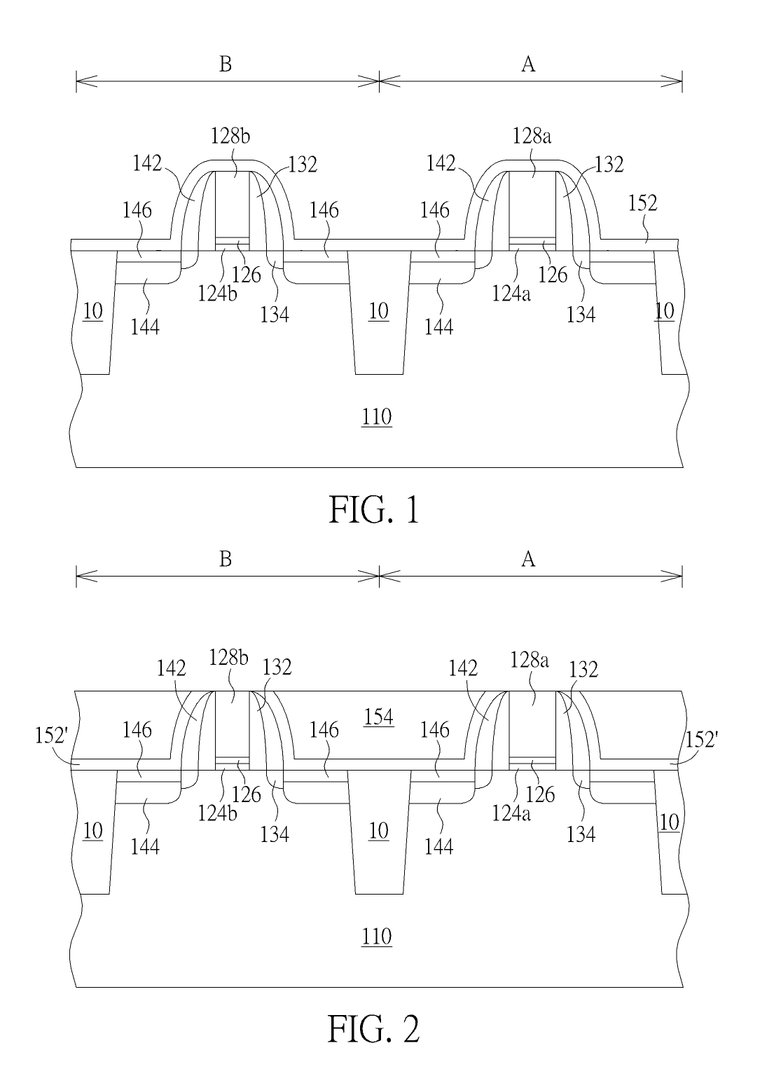

FIGS. 1-8 schematically depict cross-sectional views of an integrated circuit process according to an embodiment of the present invention. As shown in FIG. 1, a substrate 110 is provided. The substrate 110 may be divided into a flash cell area A and a logic area B. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. Isolation structures 10 are formed in the substrate 110 to electrically isolate each transistor. The isolation structures 10 may be shallow trench isolation (STI) structures, which may be formed by a shallow trench isolation process. The method of formation is known in the art, and will not be described herein.

A gate dielectric layer (not shown), a barrier layer (not shown) and a sacrificial gate layer (not shown) are sequentially formed from bottom to top and cover the substrate 110. The sacrificial gate layer, the barrier layer and the gate dielectric layer are patterned to form a first dielectric layer 124a, a barrier layer 126 and a first sacrificial gate 128a on the substrate 110 of the flash cell area A, and a second dielectric layer 124b, a barrier layer 126 and a second sacrificial gate 128b on the substrate 110 of the logic area B.

A gate-last for high-k first process is applied in this embodiment, so that the first and second dielectric layers 124a/124b are gate dielectric layers having a high dielectric constant, and may be the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST), but not limited thereto. In another embodiment, as a gate-last for high-k last process is applied, the first and second dielectric layers 124a/124b will be removed in later processes and then gate dielectric layers having a high dielectric constant are formed. Therefore, the material of the first and second dielectric layers 124a/124b may be sacrificial materials suitable for being removed in later processes. The barrier layers 126 are located on the first and second dielectric layers 124a/124b to prevent above disposed metals from diffusing downwards to the first and second dielectric layers 124a/124b and from polluting the first and second dielectric layers 124a/124b. Each of the barrier layers 126 may be a single layer structure or a multilayer structure composed of tantalum nitride (TaN) or titanium nitride (TiN), etc. The first and second sacrificial gates 128a/128b may be made of polysilicon, but are not limited thereto. Furthermore, the first and second sacrificial gates 128a/128b may respectively include a cap layer (not shown) at the top, and each of the cap layers (not shown) may be a single layer or a multilayer composed of a nitride layer or an oxide layer used for being a patterned hard mask. The first and second dielectric layers 124a/124b may optionally include buffer layers (not shown) located between the dielectric layers having a high dielectric constant and the substrate 110 to buffer the dielectric layers having a high dielectric constant and the substrate 110. The buffer layers (not shown) may be oxide layers, which may be formed through a chemical oxide process or a thermal oxide process.

First spacers 132 are formed on the substrate 110 beside the first sacrificial gate 128a and the second sacrificial gate 128b. An ion implantation process may be performed to automatically align and form lightly doped source/drain regions 134 in the substrate 110 beside the first sacrificial gate 128a and the second sacrificial gate 128b. Each of the first spacers 132 may be a single layer structure or a multilayer structure composed of silicon nitride or silicon oxide. The dopants of the lightly doped source/drain regions 134 may be trivalent ions or pentavalent ions such as boron or phosphorus.

Second spacers 142 are formed on the substrate 110 beside the first sacrificial gate 128a and the second sacrificial gate 128b. An ion implantation process is performed to automatically align and form source/drain regions 144 in the substrate 110 beside the first sacrificial gate 128a and the second sacrificial gate 128b. Each of the second spacers 142 may be a single layer structure or a multilayer structure composed of silicon nitride or silicon oxide. A salicide process may be selectively performed to form a metal silicide 146 on each of the source/drain regions 144. A contact etch stop layer 152 may be selectively formed to cover the substrate 110, the first sacrificial gate 128a and the second sacrificial gate 128b.

Thereafter, a dielectric layer (not shown) is formed to cover the substrate 110, the first sacrificial gate 128a and the second sacrificial gate 128b, and then the dielectric layer (not shown) and the contact etch stop layer 152 are planarized to form a dielectric layer 154 and a contact etch stop layer 152′, and expose the first sacrificial gate 128a and the second sacrificial gate 128b, as shown in FIG. 2. In this embodiment, the dielectric layer 154 is an interdielectric layer, but it is not limited thereto.

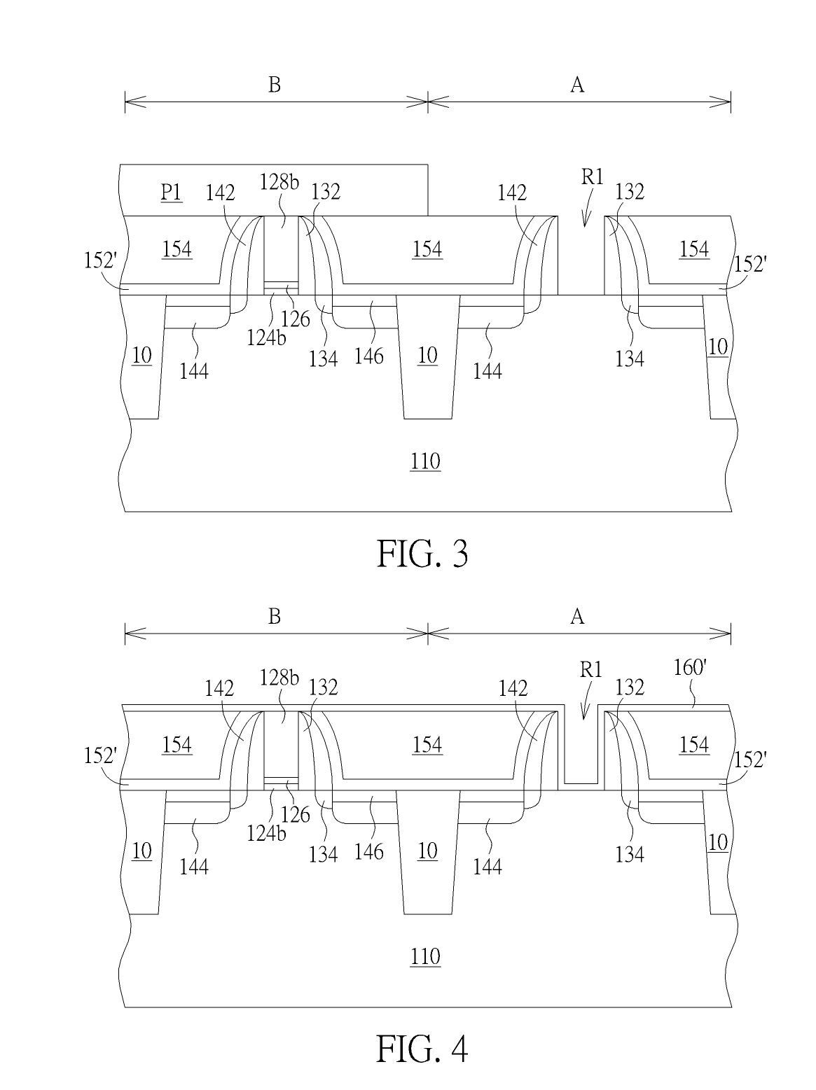

The first sacrificial gate 128a of the flash cell area A is removed by a method such as etching while the second sacrificial gate 128b of the logic area B is reserved, thereby a first recess R1 will be formed in the dielectric layer 154, as shown in FIG. 3. More precisely, a patterned first mask P1 may cover the substrate 110 of the logic area B while exposing the substrate 110 of the flash cell area A. An etching process may be performed to remove the first sacrificial gate 128a of the flash cell area A, thereby the first recess R1 will be formed. In this embodiment, the sacrificial gate 128a, the barrier layer 126 and the first dielectric layer 124a of the flash cell area A are removed and thus the substrate 110 is exposed. In another embodiment, the first dielectric layer 124a of the flash cell area A may be reserved, depending upon practical requirements. Thereafter, the patterned first mask P1 is removed. In this case, the patterned first mask P1 is a photoresist, but is not limited thereto.

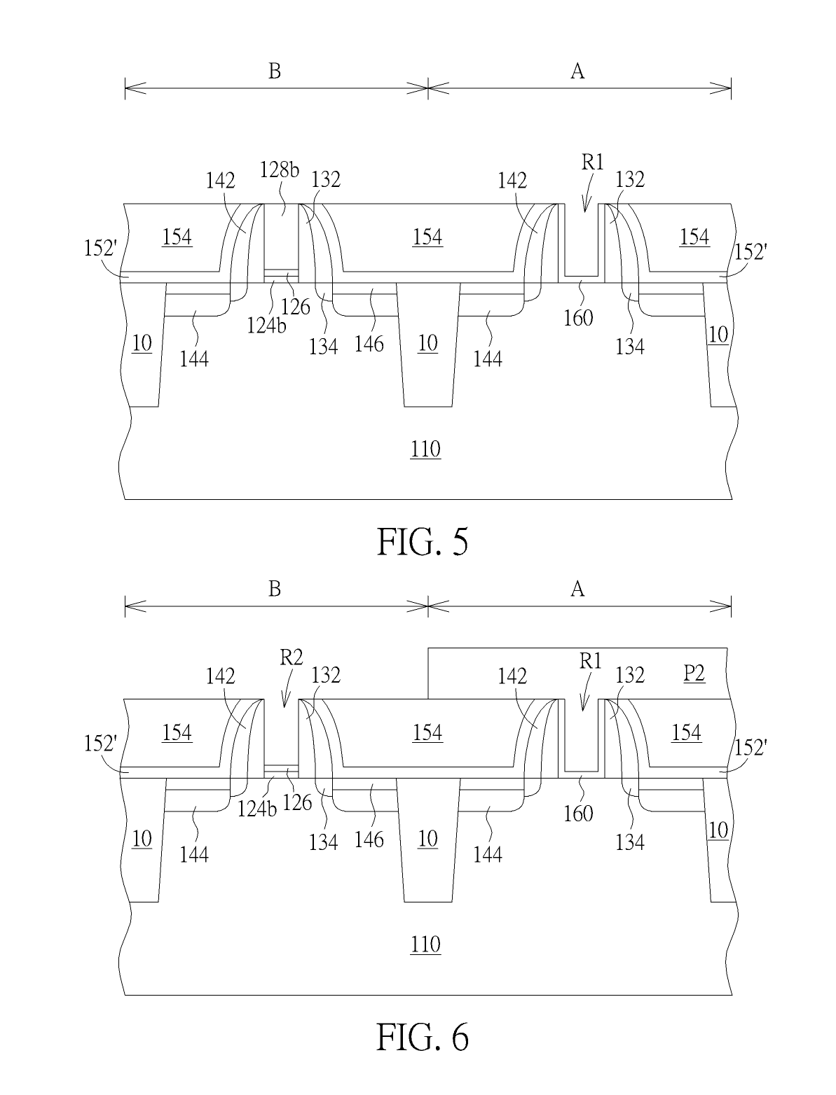

As shown in FIGS. 4-5, an oxide/nitride/oxide layer 160 is formed to conformally cover surfaces of the first recess R1. As shown in FIG. 4, an oxide/nitride/oxide layer 160′ may conformally cover the surfaces of the first recess R1, the dielectric layer 154 and the second sacrificial gate 128b. As shown in FIG. 5, a part of the oxide/nitride/oxide layer 160′ exceeding the first recess R1 is removed to form the oxide/nitride/oxide layer 160. Hence, the oxide/nitride/oxide layer 160 has a U— shaped cross-sectional profile.

The second sacrificial gate 128b is removed, as shown in FIG. 6, thereby forming the dielectric layer 154 having a second recess R2. More precisely, a patterned second mask P2 may cover the substrate 110 of the flash cell area A, the second sacrificial gate 128b is removed to form the second recess R2 in the dielectric layer 154, and the patterned second mask P2 is removed. In this embodiment, due to a gate last for high-k first process being applied, the second dielectric layer 124b and the barrier layer 126 remain. The second dielectric layer 124b will have a “-”linear-shaped cross-sectional profile while the oxide/nitride/oxide layer 160 will have a U-shaped cross-sectional profile. In another embodiment, the second dielectric layer 124b and the barrier layer 126 may be removed to expose the substrate 110, and new layers (not shown) such as a new gate dielectric layer and a new barrier layer may be reformed, depending upon practical requirements.

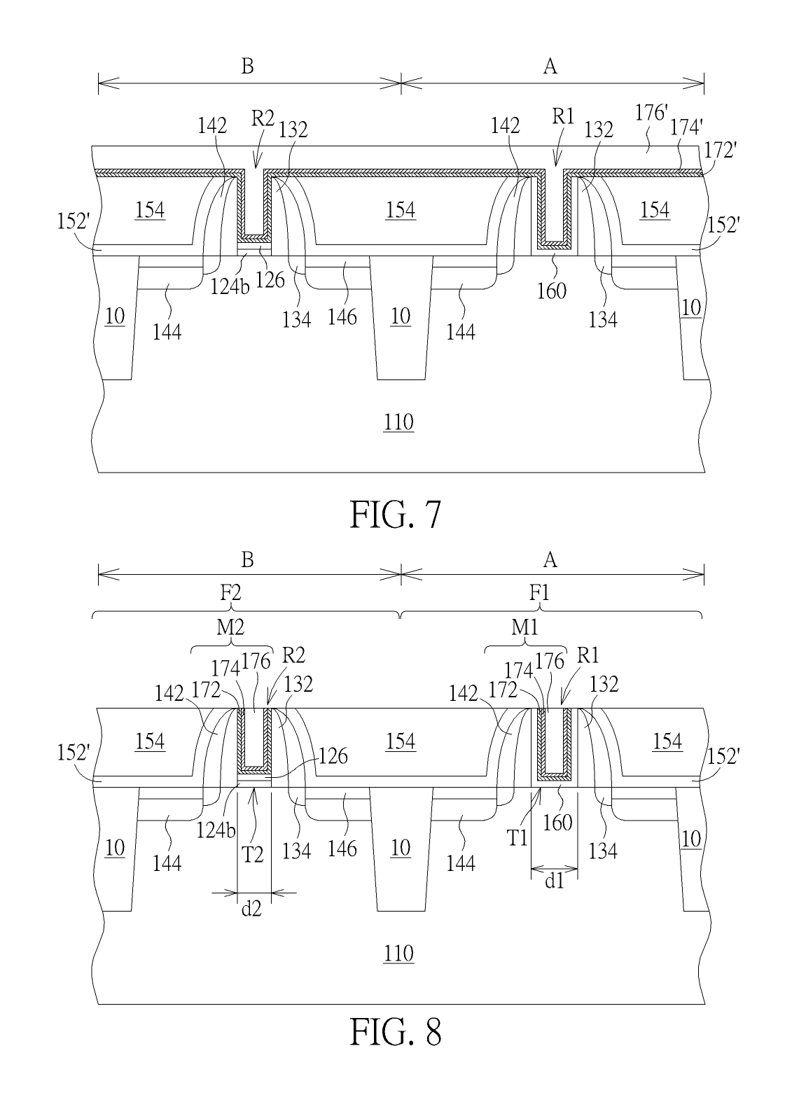

As shown in FIGS. 7-8, a first metal gate M1 is formed in the first recess R1 and a second metal gate M2 is formed in the second recess R2. In this embodiment, the first metal gate M1 and the second metal gate M2 are formed at the same time, and the first metal gate M1 is the same as the second metal gate M2, but this is not limited thereto. In another embodiment, the first metal gate M1 and the second metal gate M2 may be formed at different times. As shown in FIG. 7, a work function metal layer 172′, a barrier layer 174′ and a main conductive layer 176′ may sequentially cover the first recess R1, the second recess R2 and the dielectric layer 154. Thereafter, the main conductive layer 176′, the barrier layer 174′ and the work function metal layer 172′ may be planarized to form the first metal gate M1 and the second metal gate M2, as shown in FIG. 8. The first metal gate M1 including a work function metal layer 172, a barrier layer 174 and a main conductive layer 176 directly contacts the oxide/nitride/oxide layer 160. The second metal gate M2 including a work function metal layer 172, a barrier layer 174 and a main conductive layer 176 directly contacts the second dielectric layer 124b. A bottom surface T1 of the oxide/nitride/oxide layer 160 is trimmed with a bottom surface T2 of the second dielectric layer 124b. Since, the first metal gate M1 includes three-layers of the oxide/nitride/oxide layer 160 while the second metal gate M2 includes a single layer of the second dielectric layer 124b, the dimension d1 of the first recess R1 is preferably larger than the dimension d2 of the second recess R2 for filling gaps of the first metal gate M1.

The oxide/nitride/oxide layer 160 sandwiched by the first metal gate M1 and the substrate 110, while the dielectric layer 124b being a dielectric layer having a high dielectric constant sandwiched by the second metal gate M2 and the substrate 110 can be formed simultaneously and integrated with replacement metal gate (RMG) processes via the method of the present invention. Hence, a flash cell F1 including the first metal gate M1 and a logic cell F2 including the second metal gate M2 are fabricated at the same time, and the process steps can be simplified.

To summarize, the present invention provides an integrated circuit and process thereof, which forms a first sacrificial gate on a substrate of a flash cell area and a second sacrificial gate on the substrate of a logic area; covers a dielectric layer on the substrate beside the first sacrificial gate and the second sacrificial gate; removes the first sacrificial gate to form a first recess in the dielectric layer; and forms an oxide/nitride/oxide layer to conformally cover surfaces of the first recess. Thereafter, the second sacrificial gate may be removed to form a second recess, and then a first metal gate and a second metal gate can be formed in the first recess and the second recess at the same time. In this way, a flash cell including the first metal gate and a logic cell including the second metal gate can be fabricated; flash cells can be integrated into metal gate processes to simplify the process steps.

As a gate last for high-k first process is applied, a first dielectric layer is below the first sacrificial gate while a second dielectric layer is below the second sacrificial gate; the first sacrificial gate and the first dielectric layer are removed for forming the oxide/nitride/oxide layer conformally covering the surfaces of the first recess; and the second sacrificial gate is removed with the second dielectric layer being a dielectric layer having a high dielectric constant reserved. Thereby, the first recess preferably has a dimension larger than a dimension of the second recess to improve gap filling of the first recess having the three-layers of the oxide/nitride/oxide layer therein. The oxide/nitride/oxide layer has a U-shaped cross-sectional profile while the second dielectric layer being a dielectric layer having a high dielectric constant has a linear shaped cross-sectional profile.

Those skilled in the art will readily observe that numerous modifications and alterations of the device and method may be made while retaining the teachings of the invention. Accordingly, the above disclosure should be construed as limited only by the metes and bounds of the appended claims.

1. An integrated circuit process, comprising:
providing a substrate comprising a flash cell area and a logic area;
forming a first sacrificial gate on the substrate of the flash cell area and a second sacrificial gate on the substrate of the logic area, and covering the substrate beside the first sacrificial gate and the second sacrificial gate with a dielectric layer;
removing the first sacrificial gate to form a first recess in the dielectric layer; and
forming an oxide/nitride/oxide layer to conformally cover surfaces of the first recess, wherein the oxide/nitride/oxide layer is only in the flash cell area.

2. The integrated circuit process according to claim 1, wherein the step of removing the first sacrificial gate comprises:
covering a patterned first mask on the second sacrificial gate and then removing the first sacrificial gate.

3. The integrated circuit process according to claim 1, further comprising:
forming a first metal gate in the first recess after the oxide/nitride/oxide layer is formed.

4. The integrated circuit process according to claim 1, further comprising:
forming a first dielectric layer below the first sacrificial gate and a second dielectric layer below the second sacrificial gate after providing the substrate.

5. The integrated circuit process according to claim 1, wherein the first dielectric layer and the second dielectric layer comprise dielectric layers having a high dielectric constant.

6. The integrated circuit process according to claim 5, wherein the first dielectric layer is removed while the first sacrificial gate is removed.

7. The integrated circuit process according to claim 1, further comprising:
removing the second sacrificial gate to form a second recess in the dielectric layer after the oxide/nitride/oxide layer is formed; and
forming a second metal gate in the second recess and a first metal gate in the first recess at the same time.

8. The integrated circuit process according to claim 7, wherein the step of forming the first metal gate and the second metal gate comprises:
sequentially covering a work function metal layer, a barrier layer and a main conductive layer in the first recess, the second recess and the dielectric layer; and
planarizing the main conductive layer, the barrier layer and the work function metal layer to form the first metal gate and the second metal gate.

9. The integrated circuit process according to claim 7, wherein the step of removing the second sacrificial gate comprises:
covering a patterned second mask on the substrate of the flash cell area and then removing the second sacrificial gate.

10. The integrated circuit process according to claim 7, wherein the dimension of the first recess is larger than the dimension of the second recess.

11. The integrated circuit process according to claim 1, further comprising:
forming a first dielectric layer below the first sacrificial gate and a second dielectric layer below the second sacrificial gate after providing the substrate.

12. The integrated circuit process according to claim 11, wherein the second dielectric layer is reserved while the second sacrificial gate is removed.

13. The integrated circuit process according to claim 11, wherein the oxide/nitride/oxide layer has a bottom surface trimmed with a bottom surface of the second dielectric layer.

14. The integrated circuit process according to claim 1, further comprising:
forming a contact etch stop layer on the substrate, the first sacrificial gate and the second sacrificial gate;
forming the dielectric layer on the contact etch stop layer; and
planarizing the contact etch stop layer and the dielectric layer.

15. An integrated circuit, comprising:
a substrate comprising a flash cell area and a logic area;
a first gate disposed on the substrate of the flash cell area and a second gate disposed on the substrate of the logic area; and
an oxide/nitride/oxide layer disposed below the first gate while a dielectric layer having a high dielectric constant is disposed below the second gate.

16. The integrated circuit according to claim 15, wherein the oxide/nitride/oxide layer has a bottom surface trimmed with a bottom surface of the dielectric layer having a high dielectric constant.

17. The integrated circuit according to claim 15, wherein the first gate comprises a first metal gate, and the oxide/nitride/oxide layer is sandwiched by the first metal gate and the substrate, while the second gate comprises a second metal gate, and the dielectric layer having a high dielectric constant is sandwiched by the second metal gate and the substrate.

18. The integrated circuit according to claim 17, wherein the first metal gate is the same as the second metal gate.

19. The integrated circuit according to claim 15, further comprising:
a dielectric layer covering the substrate, wherein the first gate is disposed in a first recess of the dielectric layer while the second gate is disposed in a second recess of the dielectric layer.

20. The integrated circuit according to claim 19, wherein the dimension of the first recess is larger than the dimension of the second recess.
